(19) United States
(12) Patent Application Publication
(10) Pub. No.: US 2020/0328740 A1
(43) Pub. Date: Oct. 15, 2020

(54) METHOD OF CONTROLLING A SWITCHING VALVE

(71) Applicant: GENERAL ELECTRIC TECHNOLOGY GMBH, Baden (CH)

(72) Inventors: Francisco Javier CHIVITE ZABALZA, Stafford (GB); Pablo BRIFF, Stafford (GB); Jonathan Christopher NICHOLLS, Stafford (GB)

(73) Assignee: General Electric Technology GmbH, Baden (CH)

(21) Appl. No.: 16/304,864

(22) PCT Filed: May 26, 2017
(86) PCT No.: PCT/EP2017/062786

§ 371 Date: Nov. 27, 2018

(30) Foreign Application Priority Data
May 27, 2016 (GB) 1609384.1

(51) Int. Cl. H03K 17/567; H02M 1/088

(52) U.S. Cl. CPC H03K 17/567; H02M 1/088

(57) ABSTRACT

A switching valve includes series-connected switching elements and auxiliary circuits. Each auxiliary circuit is connected in parallel with a respective one of the series-connected switching elements. Each auxiliary circuit includes a respective auxiliary capacitor. The method includes carrying out a compensation procedure. The compensation procedure includes: initiating a turn-off event by sending a respective turn-off control signal to each switching element; measuring a respective capacitor voltage value of each auxiliary capacitor after the turn-off event; comparing the measured capacitor voltage values; and using the comparison between the measured capacitor voltages as a reference to adjust the time of sending a or a respective turn-off control signal to at least one of the switching elements so as to reduce a or a respective time difference between the turn-off times of the switching elements at the next turn-off event.

### BACKGROUND OF THE DISCLOSURE

This invention relates to a method of controlling a switching valve, and to a switching valve.

It is known to use a switching valve based on a plurality of series-connected switching elements in order to increase the overall voltage rating of the switching valve.

### BRIEF DESCRIPTION OF THE DISCLOSURE

According to a first aspect of the invention, there is provided a method of controlling a switching valve, the switching valve including a plurality of series-connected switching elements and a plurality of auxiliary circuits, each auxiliary circuit being connected in parallel with a respective one of the plurality of series-connected switching elements, each auxiliary circuit including a respective auxiliary capacitor, the method comprising the step of carrying out a compensation procedure, the compensation procedure including the sub-steps of:

initiating a turn-off event by sending a respective turn-off control signal to each switching element;

measuring a respective capacitor voltage value of each auxiliary capacitor after the turn-off event;

comparing the measured capacitor voltage values; and

using the comparison between the measured capacitor voltages as a reference to adjust the time of sending a or a respective turn-off control signal to at least one of the switching elements so as to reduce a or a respective time difference between the turn-off times of the switching elements at the next turn-off event.

The switching valve is turned off through initiation of a turn-off of the series-connected switching elements (i.e. a turn-off event) by sending a respective turn-off control signal to each switching element. When the turn-off event is initiated while a voltage is present across the switching valve (i.e. a hard-switching event), an overvoltage may appear across the switching elements, on top of any applied reverse voltage. If all of the series-connected switching elements were to turn off simultaneously, the overvoltage would be primarily proportional to any stray inductance present in a commutation loop that includes the switching valve, and also proportional to the speed at which current is turned off in the switching valve. Each series-connected switching element is normally rated to be capable of withstanding a proportionate share of the overall voltage across the switching valve when all of the switching elements are turned off.

However, in practice, it is possible that not all of the switching elements will turn off simultaneously, that is to say there is at least one time difference between the turn-off times of the switching elements. Under such circumstances, a higher overvoltage will temporarily appear across any switching element that turns off earlier, since it or they will initially experience a higher share of the overall overvoltage while the or each remaining switching element remains turned on. Consequently a given switching element may experience an overvoltage that exceeds its rating, thus potentially overstressing the switching element and thereby reducing its lifetime. This undesirable voltage sharing effect can take place in the absence of any stray inductance present in the corresponding commutation loop, but is more severe in the presence of the stray inductance.

The presence of at least one time difference between the turn-off times of the switching elements may be caused by several factors including, but not limited to, component degradation over time, unequal switching characteristics of the switching elements, delays in the sending of the turn-off control signals by the physical components of a corresponding controller, differences in the actuation of respective gate drivers associated with the switching elements, and differences in the actuation of any other component involved in the switching of the switching elements. The or each time difference between the turn-off times of the switching elements can be in the order of magnitude of nanoseconds to hundreds of seconds, and is substantially constant over time due to being affected by slow-varying variables such as ambient temperature.

The aforementioned undesirable voltage sharing effect can be avoided by way of the method of the invention in which the comparison between the measured capacitor voltages as a reference is used to adjust the time of sending a or a respective turn-off control signal to at least one of the switching elements so as to reduce the or each time difference between the turn-off times of the switching elements at the next turn-off event. This in turn not only ensures that the switching elements will be closer to simultaneous turn-off at the turn-off event which reduces the occurrence of the aforementioned undesirable voltage sharing effect, thus limiting or preventing overstressing of the switching elements and thereby preserving their lifetime, but also prevents the turn-off times of the switching elements from drifting apart which may occur due to time-varying factors, such as component degradation.

Furthermore data obtained from the compensation procedure, such as the extent of adjustment of the time of sending a or a respective turn-off control signal to at least one of the switching elements, can be used to monitor and analyse the characteristics of the switching valve, such as component degradation.

The compensation procedure may be repeated a plurality of times to enable multiple reductions of the or each time difference between the turn-off times of the switching elements at the next turn-off event. Also, the compensation procedure may be deliberately carried out during a mild or small hard-switching event to trigger the reduction of the or each time difference between the turn-off times of the switching elements in readiness for a future, severe hard switching event.

The extent of adjustment of the time of sending a or a respective turn-off control signal to at least one of the switching elements is determined by the or each difference between the measured capacitor voltages. A large difference between the measured capacitor voltages will require a correspondingly large adjustment of the time of sending a or a respective turn-off control signal to at least one of the switching elements, while a small difference between the measured capacitor voltages will require a correspondingly small adjustment of the time of sending a or a respective turn-off control signal to at least one of the switching elements.

In a conventional alternative solution to the invention, passive components may be connected to the switching elements. Such passive components are rated to ensure that the turn-off times of the switching elements are primarily dictated by the ratings of the passive components in order to equalise the turn-off times. However passive components used in this manner tend to be bulky and expensive.

The ability of the method of the invention to reduce the or each time difference between the turn-off times of the switching elements permits reduction of the size of the passive components, thus making the switching valve more cost-efficient and reliable.

In another conventional alternative solution to the invention, time differences between the turn-off times of the switching elements are measured and reduced based on voltage measurements measured instantaneously and directly across the switching elements during the turn-off event. This alternative solution is however not conducive to low levels of time difference between the turn-off times of the switching elements, which can be in the range of nanoseconds, especially when the voltages across the switching elements vary over a wide range of values. This is because measurement of such low levels of time difference between the turn-off times of the switching elements would require a high resolution (e.g. less than 100-200 V) of a voltage signal that can vary from zero or very low voltage to a few kV in a very short amount of time (e.g. a few micro-seconds), which would increase the cost and complexity of the switching valve due to the need for high measuring skill as well as high quality instrumentation and data-processing systems.

Alternatively the instantaneous voltage measurements could be replaced by continuous monitoring of the voltages across the switching elements, but such continuous monitoring would require large amounts of data storage and analysis, which would also increase the cost and complexity of the switching valve.

On the other hand the method of the invention reduces the or each time difference between the turn-off times of the switching elements at the next turn-off event based on the measured capacitor voltage values of the auxiliary capacitors. This is because, subsequent to the turn-off event, the energy storage capability of the auxiliary capacitors allows the voltage across each auxiliary capacitor to remain substantially constant at the maximum voltage, which was reached during the turn-off event, for a time that is sufficiently long to measure the capacitor voltage values in a similar manner to a DC or stationary measurement, without requiring extremely fast instrumentation and data capture electronics.

Accordingly the method of the invention is readily applicable to low levels of time difference between the turn-off times of the switching elements, such as time differences in the range of nanoseconds, even when the voltages across the switching elements vary over a wide range of values.

In addition the measured capacitor voltage values of the method of the invention can undergo filtering without sacrificing the accuracy of the compensation procedure.

The structure and configuration of the auxiliary circuits may vary so long as each auxiliary circuit includes a respective auxiliary capacitor. For example, each auxiliary circuit may include a snubber circuit, optionally wherein each snubber circuit may be a capacitor-diode snubber circuit or a resistor-capacitor-diode snubber circuit.

The method of the invention is applicable to various types of switching elements, in particular semiconductor switching elements. In addition each switching element may be a self-commutated switching element, such as an insulated gate bipolar transistor (IGBT).

In an embodiment of the invention, reducing the or each time difference between the turn-off times of the switching elements at the next turn-off event may include: minimising the or each time difference (e.g. to a near-zero or negligible time difference); or reducing the or each time difference to zero.

In a further embodiment of the invention, the sub-step of comparing the measured capacitor voltage values may include determining at least one time difference between the turn-off times of the switching elements, and the comparison between the measured capacitor voltages includes the or each determined time difference between the turn-off times of the switching elements.

In such embodiments, the method may further include the step of establishing a correlation between measured capacitor voltage value and time difference between the turn-off times of the switching elements, wherein the sub-step of comparing the measured capacitor voltage values includes determining at least one time difference between the turn-off times of the switching elements based on the correlation.

The use of the established correlation in the method of the invention results in a more effective reduction of the or each time difference between the turn-off times of the switching elements at the next turn-off event.

The correlation between measured capacitor voltage value and time difference between the turn-off times of the switching elements may be established during manufacturing or testing of the switching valve.

In such embodiments, the method may further include the step of using the comparison between the measured capacitor voltage values as a reference to adjust the correlation between measured capacitor voltage value and time difference between the turn-off times of the switching elements.

The ability to adjust the correlation based on the measured capacitor voltage values allows the correlation to be updated to correctly correspond to the present switching characteristics of the switching valve which may change over time. For example, the correlation may requiring updating due to the degradation of one or more components of the switching valve over time.

The method of controlling a switching valve of the invention may further include the steps of:

grouping the plurality of series-connected switching elements into a plurality of groups, each group including two or more of the plurality of series-connected switching elements;

for each group, carrying out the compensation procedure for the switching elements of the same group; and

then carrying out the compensation procedure for the switching elements of the plurality of groups.

In this manner the reduction of the or each time difference between the turn-off times of the switching elements at the next turn-off event is carried out within each group, before reduction of the or each time difference between the turn-off times of the switching elements at the next turn-off event is carried out between the plurality of groups. This provides a more time-efficient and less computation intensive way of reducing the or each time difference between the turn-off times of the switching elements at the next turn-off event.

The step of carrying out the compensation procedure for the switching elements of the same group may include:

initiating a turn-off event by sending a respective turn-off control signal to each switching element of the same group;

measuring a respective capacitor voltage value of each auxiliary capacitor of the same group after the turn-off event;

comparing the measured capacitor voltage values of the same group; and

using the comparison between the measured capacitor voltages of the switching elements of the same group as a reference to adjust the time of sending the turn-off control signal to at least one of the switching elements of the same group so as to reduce the or each time difference between the turn-off times of the switching elements of the same group at the next turn-off event.

The step of carrying out the compensation procedure for the switching elements of multiple groups may include:

initiating a further turn-off event by sending a respective turn-off control signal to each switching element of the multiple groups;

measuring a respective capacitor voltage value of each auxiliary capacitor of the multiple groups after the turn-off event;

comparing the measured capacitor voltage values of the multiple groups; and

using the comparison between the measured capacitor voltages of the multiple groups as a reference to adjust the time of sending the turn-off control signal to at least one of the switching elements of the multiple groups so as to reduce the or each time difference between the turn-off times of the switching elements of the multiple groups at the next turn-off event.

In embodiments of the invention, the step of carrying out the compensation procedure for the switching elements of the plurality of groups may include:

carrying out the compensation procedure for the switching elements of a set of groups, wherein the set of groups includes two or more of the plurality of groups;

adding one or more of the plurality of groups to the set of groups; and

then carrying out the compensation procedure for the switching elements of the set of groups including the or each additional group.

In such embodiments, the method may further include the step of ordering the groups in a hierarchal arrangement, and the step of carrying out the compensation procedure for the switching elements of the plurality of groups may include:

carrying out the compensation procedure for the switching elements of the set of groups, wherein the set of groups is ordered first in the hierarchal arrangement;

adding one or more of the plurality of groups to the set of groups, wherein the or each additional group is ordered next in the hierarchal arrangement; and

then carrying out the compensation procedure for the switching elements of the set of groups including the or each additional group.

Such steps result in a reliable means for reducing the time and computational complexity of reducing the or each time difference between the turn-off times of the switching elements at the next turn-off event.

In embodiments of the invention employing the use of the hierarchal arrangement, the method may further include the step of randomising the order of the groups in the hierarchal arrangement and/or randomising the type of hierarchal arrangement used, prior to the step of carrying out the compensation procedure for the switching elements of the plurality of groups.

This approach not only enhances the outcome of the method of the invention, but also prevents the method of the invention from being adversely affected by a steady-state bias that might arise as a result of relying on a specific hierarchal arrangement.

The hierarchal arrangement may, for example, include a tree or star topology.

According to a second aspect of the invention, there is provided a switching valve comprising a plurality of series-connected switching elements and a plurality of auxiliary circuits, each auxiliary circuit being connected in parallel with a respective one of the plurality of series-connected switching elements, each auxiliary circuit including a respective auxiliary capacitor,

wherein the switching valve further includes a controller programmed to carry out a compensation procedure, the controller is programmed to initiate a turn-off event by sending a respective turn-off control signal to each switching element, the controller includes a measuring device configured to measure a respective capacitor voltage value of each auxiliary capacitor after the turn-off event, the controller is programmed to compare the measured capacitor voltage values; and the controller is programmed to use the comparison between the measured capacitor voltages as a reference to adjust the time of sending a or a respective turn-off control signal to at least one of the switching elements so as to reduce a or a respective time difference between the turn-off times of the switching elements at the next turn-off event.

The features of the method of the first aspect of the invention and its embodiments apply mutatis mutandis to the switching valve of the second aspect of the invention and its embodiments.

The structure and the configuration of the controller may vary.

In embodiments of the invention, the controller may include a plurality of local control units and a higher-level control unit, each local control unit may be programmed to send a respective turn-off control signal to the corresponding switching element, each local control unit may be configured to be in communication with the higher-level control unit, each local control unit may be programmed to transmit the measured capacitor voltage value of the corresponding auxiliary capacitor to the higher-level control unit, the higher-level control unit may be programmed to compare the measured capacitor voltage values and to use the comparison between the measured capacitor voltages as a reference to adjust the time of sending a or a respective turn-off control signal to at least one of the switching elements so as to reduce a or a respective time difference between the turn-off times of the switching elements at the next turn-off event, and the higher-level control unit may be programmed to transmit the or each adjusted time to the or each corresponding local control unit.

Each local control unit may be configured to be in communication with the higher-level control unit via a passive optical network.

In embodiments of the switching valve of the invention, each auxiliary circuit may include a snubber circuit, optionally wherein each snubber circuit may be a capacitor-diode snubber circuit or a resistor-capacitor-diode snubber circuit.

In further embodiments of the switching valve of the invention, each switching element may be a self-commutated switching element, such as an IGBT.

In still further embodiments of the switching valve of the invention, reducing the or each time difference between the turn-off times of the switching elements at the next turn-off event may include: minimising the or each time difference; or reducing the or each time difference to zero.

The controller may be programmed to compare the measured capacitor voltage values so as to determine at least one time difference between the turn-off times of the switching elements, and the comparison between the measured capacitor voltages may include the or each determined time difference between the turn-off times of the switching elements.

The controller may be programmed to compare the measured capacitor voltage values so as to determine at least one time difference between the turn-off times of the switching elements based on a correlation between measured capacitor voltage value and time difference between the turn-off times of the switching elements.

The controller may be programmed to establish a correlation between measured capacitor voltage value and time difference between the turn-off times of the plurality of series-connected switching elements. Additionally or alternatively, the controller may be programmed to store a correlation that is established by other means.

The controller may be programmed to use the comparison between the measured capacitor voltage values as a reference to adjust the correlation between measured capacitor voltage value and time difference between the turn-off times of the switching elements.

The controller may be programmed to:

group the plurality of series-connected switching elements into a plurality of groups, each group including two or more of the plurality of series-connected switching elements;

for each group, carry out the compensation procedure for the switching elements of the same group; and

then carry out the compensation procedure for the switching elements of the plurality of groups.

The controller may be programmed to carry out the compensation procedure for the switching elements of the plurality of groups by:

carrying out the compensation procedure for the switching elements of a set of groups, wherein the set of groups includes two or more of the plurality of groups;

adding one or more of the plurality of groups to the set of groups; and

then carrying out the compensation procedure for the switching elements of the set of groups including the or each additional group.

The controller may be programmed to order the groups in a hierarchal arrangement, and the controller may be further programmed to carry out the compensation procedure for the switching elements of the plurality of groups by:

carrying out the compensation procedure for the switching elements of the set of groups, wherein the set of groups is ordered first in the hierarchal arrangement;

adding one or more of the plurality of groups to the set of groups, wherein the or each additional group is ordered next in the hierarchal arrangement; and

then carrying out the compensation procedure for the switching elements of the set of groups including the or each additional group.

The controller may be programmed to randomise the order of the groups in the hierarchal arrangement and/or randomise the type of hierarchal arrangement used, prior to carrying out the compensation procedure for the switching elements of the plurality of groups.

The hierarchal arrangement may include a tree or star topology.

It will be understood that the plurality of series-connected switching elements with reference to the invention may comprise: all of the series-connected switching elements in the switching valve; or some of the series-connected switching elements in a valve, i.e. a group of series-connected switching elements forming part of a larger group of series-connected switching elements.

The invention is applicable to a range of applications that require the use of a switching valve based on a plurality of series-connected switching elements. Such applications include, but are not limited to, high voltage direct current transmission, voltage source converters (VSC), modular multilevel converters (MMC), alternate arm converters (AAC), semiconductor switching valves, and chain-link converters.

### BRIEF DESCRIPTION OF THE DRAWINGS

An embodiment of the invention will now be described, by way of a non-limiting example, with reference to the accompanying drawings in which:

FIG. 1 schematically shows a switching valve according to an embodiment of the invention;

FIG. 2 shows a resistor-capacitor-diode circuit;

FIG. 3 shows a simulation model of the switching valve of FIG. 1;

FIGS. 4A to 4C illustrate the results of the simulation model of FIG. 3;

FIG. 5 shows a control loop of the controller of the switching valve of FIG. 1;

FIG. 6 illustrates the results of a feasibility evaluation using the simulation model of FIG. 3;

FIG. 7 illustrates the results of a feasibility evaluation using an experimental setup of the switching valve of FIG. 1; and

FIGS. 8 and 9 show hierarchal arrangements of the switching elements of the switching valve of FIG. 1.

### DETAILED DESCRIPTION

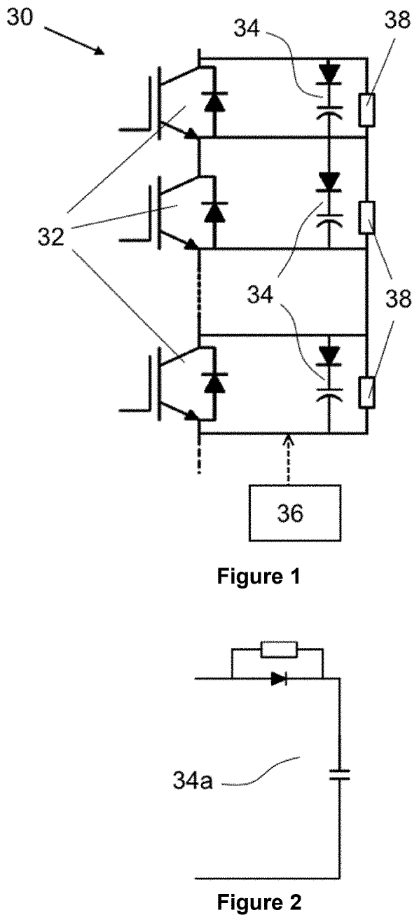

A switching valve according to an embodiment of the invention is shown in FIG. 1 and is designated generally by the reference numeral 30.

The switching valve 30 includes a plurality of series-connected switching elements 32, a plurality of auxiliary circuits 34, and a controller 36.

In the embodiment shown, each switching element 32 is in the form of an IGBT 32 but may be replaced by another type of switching element 32 in other embodiments.

Each auxiliary circuit 34 is connected in parallel with a respective one of the plurality of series-connected IGBTs 32. Each auxiliary circuit 34 includes a capacitor-diode snubber circuit connected in parallel with a resistor 38. It will be appreciated that the resistor 38 is an optional component. In other embodiments of the invention, it is envisaged that the capacitor-diode snubber circuit may be replaced by a resistor-capacitor-diode circuit, as shown in FIG. 2.

The capacitor in each auxiliary circuit 34 will be referred to hereon in this specification as the auxiliary capacitor. The auxiliary capacitor in each auxiliary circuit 34 can be used to mitigate voltage overshoot during a turn-off transient event, and to store enough energy to supply power to drive the control electronics of the corresponding IGBT 32.

The controller 36 is programmed to control the switching of the IGBTs 32, and includes the control electronics of each IGBT 32. In particular, the controller 36 is programmed to initiate a turn-off event by sending a respective turn-off control signal to each IGBT 32, and initiate a turn-on event by sending a respective turn-on control signal to each IGBT 32.

It is envisaged that, in other embodiments of the invention, the local control electronics of each IGBT may perform its control function(s) upon reception of a global command or delay parameter from a global control unit.

During the turn-off event, it is possible that not all of the IGBTs 32 will turn off simultaneously, that is to say there is at least one time difference between the turn-off times of the IGBTs 32, which may arise as a result of various factors (some of which are discussed earlier in this specification). The or each time difference between the turn-off times of the IGBTs 32 results in an undesirable voltage sharing effect in which any IGBT 32 that turns off earlier will initially experience a higher share of the overall overvoltage while the or each remaining IGBT 32 remains turned on.

It is therefore desirable to reduce the or each time difference between the turn-off times of the IGBTs 32 to reduce the occurrence of the aforementioned undesirable voltage sharing effect. Such a reduction of each time difference involves minimising the or each time difference between the turn-off times of the IGBTs 32 (e.g. to a near-zero or negligible time difference); or reducing the or each time difference between the turn-off times of the IGBTs 32 to zero.

The presence of at least one time difference between the turn-off times of the IGBTs 32 results in at least one voltage difference between the capacitor voltage values of the auxiliary capacitors.

The inventors have found that it is possible to effectively reduce the or each time difference between the turn-off times of the IGBTs 32 based on a correlation between the capacitor voltage values of the auxiliary capacitors and the or each time difference between the turn-off times of the IGBTs 32.

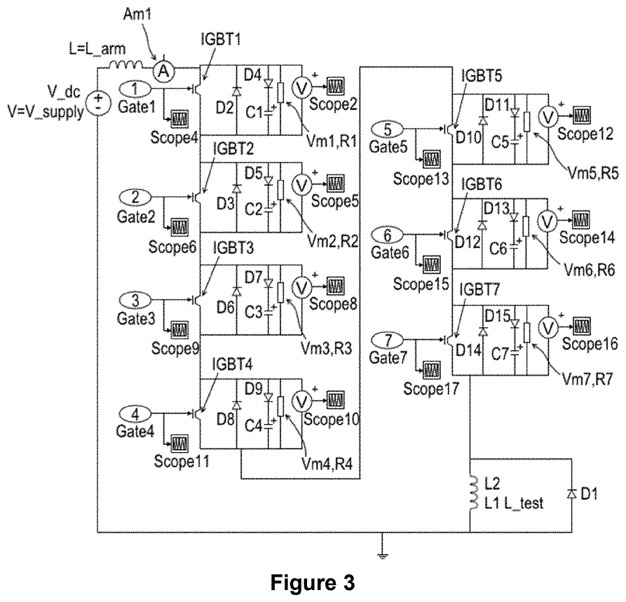

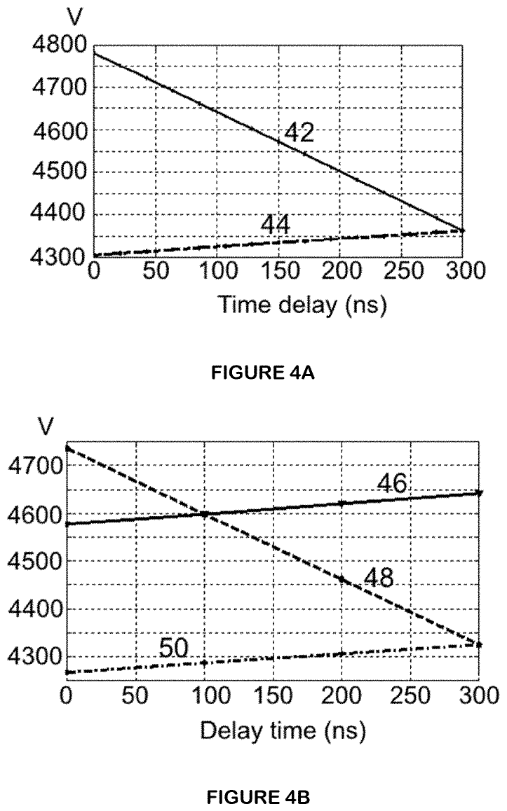

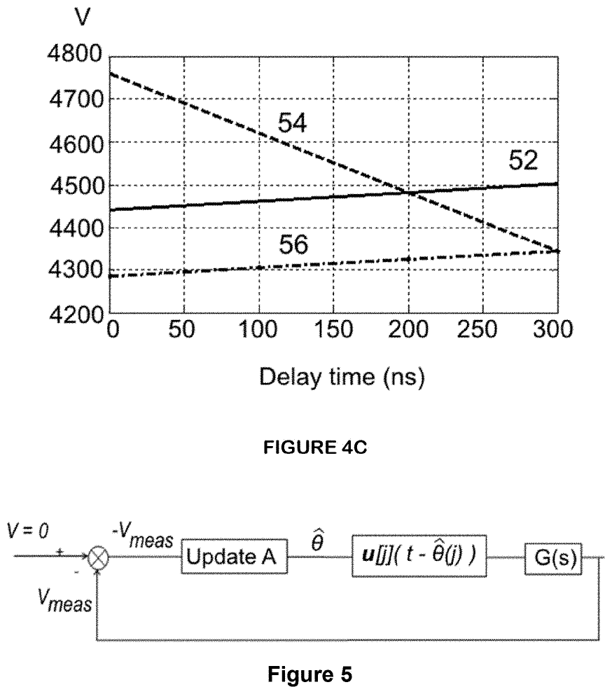

The correlation between the capacitor voltage values and the or each time difference between the turn-off times of the IGBTs 32 is characterised as follows, with reference to FIGS. 3 and 4A to 4C.

FIG. 3 schematically shows a PLECS simulation model using a Simulink platform. The simulation model is based on a switching valve 30 comprising seven series-connected IGBTs 32. In the simulation model, the IGBTs 32 are subjected to a double pulse test at turn-off current of 1500 A and at 8750 V, and the maximum capacitor voltage value of each auxiliary capacitor during the turn-off event of the switching valve 30 is recorded.

In a first characterisation test, the delay of the turn-off time of the 1^{st} IGBT 32 with respect to a master turn-off control signal is varied between 0 to 300 ns, and the turn-off time of the 2^{nd} to 7^{th} IGBTs 32 are delayed by 300 ns with respect to the master turn-off control signal.

It can be seen in FIG. 4A that the turn-off of the 1^{st} IGBT 32 in advance of the other IGBTs 32 results in a voltage difference between the capacitor voltage value 42 corresponding to the 1^{st} IGBT 32 and the capacitor voltage values 44 corresponding to the other IGBTs 32. For example, the turn-off of the 1^{st} IGBT 32 by 300 ns in advance of the other IGBTs 32 results in an approximately 500 V voltage difference between the capacitor voltage value 42 corresponding to the 1^{st} IGBT 32 and the capacitor voltage values 44 corresponding to the other IGBTs 32. Moreover, there is a linear relationship between: the voltage difference between the capacitor voltage value 42 corresponding to the 1^{st} IGBT 32 and the capacitor voltage value 44 corresponding to any of the other IGBTs 32; and the time difference between the turn-off times of the 1^{st} IGBT 32 and any of the other IGBTs 32.

In a second characterisation test, the delay of the turn-off time of the 1^{st} IGBT 32 with respect to a master turn-off control signal is set at 100 ns and 200 ns, the delay of the turn-off time of the 2^{nd} IGBT 32 with respect to the master turn-off control signal is varied between 0 to 300 ns, and the turn-off time of the 3^{rd} to 7^{th} IGBTs 32 are delayed by 300 ns with respect to the master turn-off control signal. In other words, the second characterisation test involves multiple time differences between the turn-off times of the IGBTs 32.

FIG. 4B illustrates the correlation between the capacitor voltage values and the or each time difference between the turn-off times of the IGBTs 32 when the delay of the turn-off time of the 2^{nd} IGBT 32 with respect to the master turn-off control signal was carried out in four steps from 0 to 300 ns, and the delay of the turn-off time of the 1^{st} IGBT 32 with respect to the master turn-off control signal is fixed at 100 ns. It can be seen in FIG. 4B that, although the absolute voltage values vary in comparison to FIG. 4A, there is a constant voltage difference between the capacitor voltage value 46 corresponding to the 1^{st} IGBT 32 and the capacitor voltage value 50 corresponding to any of the 3^{rd} to 7^{th} IGBTs 32, since the time difference between the turn-off times of the 1^{st} IGBT 32 and any of the 3^{rd} to 7^{th} IGBTs 32 is constant at 100 ns.

FIG. 4C illustrates the correlation between the capacitor voltage values and the or each time difference between the turn-off times of the IGBTs 32 when the delay of the turn-off time of the 2^{nd} IGBT 32 with respect to the master turn-off control signal was carried out in four steps from 0 to 300 ns, and the delay of the turn-off time of the 1^{st} IGBT 32 with respect to the master turn-off control signal is fixed at 200 ns. It can be seen in FIG. 4C that, although the absolute voltage values vary in comparison to FIGS. 4A and 4B, there is a constant voltage difference between the capacitor voltage value 46 corresponding to the 1^{st} IGBT 32 and the capacitor voltage value 50 corresponding to any of the 3^{rd} to 7^{th} IGBTs 32, since the time difference between the turn-off times of the 1^{st} IGBT 32 and any of the 3^{rd} to 7^{th} IGBTs 32 is constant at 200 ns.

It can also be seen from both FIGS. 4B and 4C that there is a linear relationship between: the voltage difference between the capacitor voltage value 48 corresponding to the 2^{nd} IGBT 32 and the capacitor voltage value 50 corresponding to any of the 3^{rd} to 7^{th} IGBTs 32; and the time difference between the turn-off times of the 2nd IGBT 32 and any of the 3^{rd} to 7^{th} IGBTs 32, and that this linear relationship is the same as the one shown in FIG. 4A.

Therefore, in view of the foregoing, it is evident that the voltage difference between the capacitor voltage values corresponding to two of the series-connected IGBTs 32 bears a linear relationship with the time difference between the turn-off times of the two same IGBTs 32, and this linear relationship is substantially unaffected by the turn-off times of the other IGBTs 32 in the same series connection. Moreover this linear relationship can be, for instance, measured during End of Line Testing during manufacture, or following a characterization routine of the switching valve 30. This may involve, for example, the triggering of switching events at a low current level.

The controller 36 is programmed to carry out a compensation procedure to reduce the or each time difference between the turn-off times of the IGBTs 32 at the next turn-off event based on this correlation.

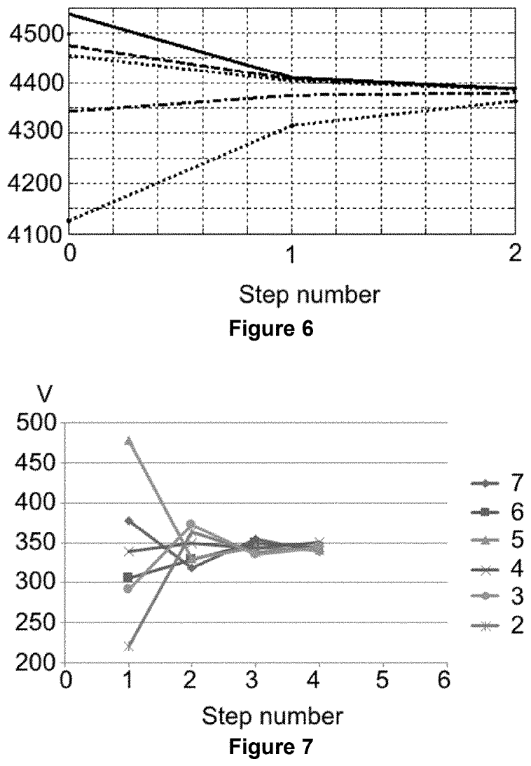

The compensation procedure is described as follows for a switching valve 30 with N series-connected IGBTs 32, with reference to FIGS. 5, 6a and 6b.

The controller 36 includes a measuring device (e.g. a voltage sensor) configured to measure a respective capacitor voltage value of each auxiliary capacitor after the turn-off event. This allows the controller 36 to obtain measured capacitor voltage values for use in the compensation procedure.

The use of the measured capacitor voltage values in the compensation procedure is advantageous in that, subsequent to the turn-off event, the energy storage capability of the auxiliary capacitors allows the voltage across each auxiliary capacitor to remain substantially constant at the maximum voltage, which was reached during the turn-off event, for a time that is sufficiently long to measure the capacitor voltage values in a similar manner to a DC or stationary measurement.

The correlation between the voltage difference Vᵢⱼ of the measured capacitor voltage values of the IGBTs 32 Tᵢ and Tⱼ and a time difference δᵢⱼ between the turn-off times of the IGBTs 32 Tᵢ and Tⱼ can be stated as:

Vᵢⱼ=aᵢⱼδᵢⱼ i,j=1,2, . . . ,N (1)

where aᵢⱼ are the linear coefficients of the correlation with respect to a given pair of IGBTs 32.

By defining the diagonal matrix A as

A=diag[a₁_{ⱼ}]∈ [symbol] ^{(N-1)×(N-1)}j=2,3, . . . ,N (2)

then the following relationship can be stated:

V=A·θ (3)

Where

$$\begin{matrix}V = [ \begin{matrix}{V}_{12} \\ {V}_{13} \\ ⋮ \\ {V}_{1 N}\end{matrix} ] \\ and & ( 4 ) \\ θ = [ \begin{matrix}{δ}_{12} \\ {δ}_{13} \\ ⋮ \\ {δ}_{1 N}\end{matrix} ] & ( 5 )\end{matrix}$$

The vector θ is a relative offset vector between an arbitrary IGBT 32 T₁ and the remaining IGBTs 32 Tⱼ, with j=2, 3, . . . , N.

Therefore, an estimate of θ, denoted as \hat{θ}, can be obtained from (3) as:

\hat{θ}=A⁻¹·V (6)

with A⁻¹=diag(1/a₁ⱼ)

The value of \hat{θ} is used as a reference value to adjust the time of sending a or a respective turn-off control signal to at least one of the IGBTs 32 so as to reduce a or a respective time difference between the turn-off times of the IGBTs 32 at the next turn-off event. In particular, the turn-off control signal sent to a given IGBT 32 is adjusted (if necessary) by an amount given by \hat{θ} with respect to the turn-off time corresponding to an arbitrary IGBT 32, without loss of generality. Namely, the turn-off control signal sent to IGBT 32 Tⱼ is to be adjusted as follows:

u₁=u[j] (t−\hat{θ}(j))j=2,3, . . . ,N (7)

where u is the vector of the turn-off control signals sent to the IGBTs 32, and u[j] is the turn-off control signal sent to IGBT 32 Tⱼ.

The objective is to perform the compensation procedure to issue a control setting that achieves V=0, i.e. there is no voltage difference observed between the capacitor voltage values of any pair of the IGBTs 32 at the next turn-off event. This may involve repeating the compensation procedure a plurality of times to enable multiple reductions of the or each time difference between the turn-off times of the IGBTs 32 at the next turn-off event.

The controller 36 may include an adaptive closed loop control, an example of which is shown in FIG. 5, in which the comparison between the measured capacitor voltages is used as a reference to adjust the linear coefficients aᵢⱼ of the correlation, thereby enabling the online updating of the diagonal matrix A. This is so that the correlation, and therefore the diagonal matrix A, can be updated to correctly correspond to the present switching characteristics of the switching valve 30 which may change over time.

Considering that any time difference δᵢⱼ is defined as the difference between two absolute times δᵢ₀ and δⱼ₀, calculated with respect to the start of a processor scan cycle declared as time zero, denoted as T₀=0, then the turn-off time for IGBT 32 T₁ is determined by:

$${T}_{1}^{*} = \{ \begin{matrix}- min ( \hat{θ} ) , & if min ( \hat{θ} ) < 0 \\ 0 , & otherwise\end{matrix} \qquad ( 8 )$$

which guarantees at time T₀ the fastest IGBT 32 will receive the corresponding turn-off control signal. Since real systems can only be causal, it is not possible for any IGBT 32 to be turned off before T₁* as presented by (8).

It is also possible to calculate the reference time T₁* from obtaining the average, maximum, minimum or any other signal processing technique applied to the offset vector θ, as long as all the IGBTs 32 are fired at causal time and the turn-off times for the IGBTs 32 do not result in unacceptable delays that can jeopardise the health and safety of the switching valve 30.

Therefore, using (8), the turn-off times of the remaining IGBTs 32 are obtained as:

Tⱼ=T₁*+δ₁ⱼ for j=2,3, . . . ,N (9)

In this manner the controller 36 is programmed to use the comparison between the measured capacitor voltages as a reference to adjust the time of sending a or a respective turn-off control signal to at least one of the IGBTs 32 so as to reduce a or a respective time difference between the turn-off times of the IGBTs 32 at the next turn-off event.

After the compensation procedure is complete, the auxiliary capacitors can be discharged by other means, such as gate driver load, floating supply circuitry or activation of a crowbar circuit.

The ability to reduce the or each time difference between the turn-off times of the IGBTs 32 not only permits reduction of the size of associated passive components, but also obviates the need for extremely fast instrumentation and data capture electronics as a result of the use of the measured capacitor voltage values of the auxiliary capacitors.

The simulation model of FIG. 3 is used to evaluate the feasibility of the compensation procedure.

In the feasibility evaluation using the simulation model, the turn-off time of each of the 1st to 7th IGBTs 32 is delayed, with respect to a master turn-off signal, by the following times: −25 ns, 15 ns, 120 ns, 30 ns, 250 ns, 300 ns, 0 ns, respectively. Moreover, the linear coefficients of the correlation between: the voltage difference between the capacitor voltage values of any two IGBTs 32 and the time difference between the turn-off times of the same two IGBTs 32 is set at 500 V/300 ns.

FIG. 6 illustrates the results of the feasibility evaluation using the simulation model. It can be seen in FIG. 6 that the measured capacitor voltage values converge to approximately the same value after two iterations of the compensation procedure, which indicates that the compensation procedure was successful in reducing the time differences between the turn-off times of the IGBTs 32.

An experimental setup of the switching valve 30 of FIG. 1 was also used to evaluate the feasibility of the compensation procedure.

FIG. 7 illustrates the results of the feasibility evaluation using the experimental setup. It can be seen in FIG. 7 that the measured capacitor voltage values converge to approximately the same value after three iterations of the compensation procedure, which is in accordance with the predicted behaviour shown in FIG. 6.

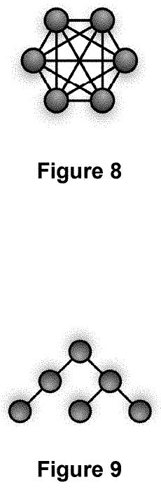

For a high number of series-connected IGBTs 32, the compensation procedure can be computationally intensive if applied at the same time to all of the IGBTs 32 in accordance with a hierarchal arrangement of the switching elements 32, where the hierarchal arrangement is based on a fully-meshed topology which has an algorithmic complexity of O(N²). The fully-meshed topology is shown in FIG. 8.

The computation complexity of the compensation procedure can be reduced by using a different hierarchal arrangement of the switching elements 32 when performing the compensation procedure.

For example, the controller 36 may be programmed to group the plurality of series-connected IGBTs 32 into a plurality of groups, where each group including two or more of the plurality of series-connected IGBTs 32; for each group, carrying out the compensation procedure for the IGBTs 32 of the same group; and then carrying out the compensation procedure for the IGBTs 32 of the plurality of groups.

In this manner the reduction of the or each time difference between the turn-off times of the IGBTs 32 at the next turn-off event is carried out within each group, before reduction of the or each time difference between the turn-off times of the IGBTs 32 at the next turn-off event is carried out between the plurality of groups. This provides a more time-efficient and less computation intensive way of reducing the or each time difference between the turn-off times of the IGBTs 32 at the next turn-off event.

The compensation procedure for the IGBTs 32 of the same group may be carried out by:

initiating a turn-off event by sending a respective turn-off control signal to each IGBT 32 of the same group;

measuring a respective capacitor voltage value of each auxiliary capacitor of the same group after the turn-off event;

comparing the measured capacitor voltage values of the same group; and

using the comparison between the measured capacitor voltages of the IGBTs 32 of the same group as a reference to adjust the time of sending the turn-off control signal to at least one of the IGBTs 32 of the same group so as to reduce the or each time difference between the turn-off times of the IGBTs 32 of the same group at the next turn-off event.

The compensation procedure for the IGBTs 32 of multiple groups may be carried out by:

initiating a further turn-off event by sending a respective turn-off control signal to each IGBT 32 of the multiple groups;

measuring a respective capacitor voltage value of each auxiliary capacitor of the multiple groups after the turn-off event;

comparing the measured capacitor voltage values of the multiple groups; and

using the comparison between the measured capacitor voltages of the multiple groups as a reference to adjust the time of sending the turn-off control signal to at least one of the IGBTs 32 of the multiple groups so as to reduce the or each time difference between the turn-off times of the IGBTs 32 of the multiple groups at the next turn-off event.

The different hierarchal arrangement may be based on a tree topology shown in FIG. 9, or a star topology which has an algorithmic complexity of O(N log(N)). Therefore, the compensation procedure for the IGBTs 32 of the plurality of groups may be carried out by:

carrying out the compensation procedure for the IGBTs 32 of the set of groups, wherein the set of groups is ordered first in the hierarchal arrangement;

adding one or more of the plurality of groups to the set of groups, wherein the or each additional group is ordered next in the hierarchal arrangement; and

then carrying out the compensation procedure for the IGBTs 32 of the set of groups including the or each additional group.

Optionally the order of the groups in the hierarchal arrangement may be randomised and/or the type of hierarchal arrangement used may be randomised, prior to carrying out the compensation procedure for the IGBTs 32 of the plurality of groups. This approach not only enhances the outcome of the compensation procedure, but also prevents the compensation procedure from being adversely affected by a steady-state bias that might arise as a result of relying on a specific hierarchal arrangement.

Optionally, in embodiments of the invention, the controller may include a plurality of local control units and a higher-level control unit. Each local control unit may be programmed to send a respective turn-off control signal to the corresponding IGBT 32. Each local control unit may be configured to be in communication with the higher-level control unit via a passive optical network. Each local control unit may be programmed to transmit the measured capacitor voltage value of the corresponding auxiliary capacitor to the higher-level control unit. The higher-level control unit may be programmed to compare the measured capacitor voltage values and to use the comparison between the measured capacitor voltages as a reference to adjust the time of sending a or a respective turn-off control signal to at least one of the IGBTs 32 so as to reduce a or a respective time difference between the turn-off times of the IGBTs 32 at the next turn-off event. The higher-level control unit may be programmed to transmit the or each adjusted time to the or each corresponding local control unit.

1. A method of controlling a switching valve, the switching valve including a plurality of series-connected switching elements and a plurality of auxiliary circuits, each auxiliary circuit being connected in parallel with a respective one of the plurality of series-connected switching elements, each auxiliary circuit including a respective auxiliary capacitor, the method comprising carrying out a compensation procedure, the compensation procedure including:
initiating a turn-off event by sending a respective turn-off control signal to each switching element;
measuring a respective capacitor voltage value of each auxiliary capacitor after the turn-off event;
comparing the measured capacitor voltage values; and
using the comparison between the measured capacitor voltages as a reference to adjust the time of sending a or a respective turn-off control signal to at least one of the switching elements so as to reduce a or a respective time difference between the turn-off times of the switching elements at the next turn-off event.

2. The method according to claim 1, wherein each auxiliary circuit includes a snubber circuit.

3. The method according to claim 2, wherein each snubber circuit is a capacitor-diode snubber circuit or a resistor-capacitor-diode snubber circuit.

4. The method according to claim 1, wherein each switching element is a self-commutated switching element.

5. The method according to claim 1 wherein reducing the or each time difference between the turn-off times of the switching elements, at the next turn-off event includes: minimising the or each time difference; or
reducing the or each time difference to zero.

6. The method according to claim 1, wherein comparing the measured capacitor voltage values includes determining at least one time difference between the turn-off times of the switching elements, and the comparison between the measured capacitor voltages includes the or each determined time difference between the turn-off times of the switching elements.

7. The method according to claim 6, further including the step of establishing a correlation between measured capacitor voltage value and time difference between the turn-off times of the switching elements, wherein the sub step of comparing the measured capacitor voltage values includes determining at least one time difference between the turn-off times of the switching elements based on the correlation.

8. The method according to claim 7, further including using the comparison between the measured capacitor voltage values as a reference to adjust the correlation between measured capacitor voltage value and time difference between the turn-off times of the switching elements.

9. The method according to claim 1, further including:
grouping the plurality of series-connected switching elements (32) into a plurality of groups, each group including two or more of the plurality of series-connected switching elements;
for each group, carrying out the compensation procedure for the switching elements (32) of the same group; and
then carrying out the compensation procedure for the switching elements (32) of the plurality of groups.

10. The method according to claim 9, wherein carrying out the compensation procedure for the switching elements of the plurality of groups includes:
carrying out the compensation procedure for the switching elements of a set of groups, wherein the set of groups includes two or more of the plurality of groups;
adding one or more of the plurality of groups to the set of groups; and
then carrying out the compensation procedure for the switching elements of the set of groups including the or each additional group.

11. The method according to claim 10, further including ordering the groups in a hierarchal arrangement, and carrying out the compensation procedure for the switching elements of the plurality of groups includes:
carrying out the compensation procedure for the switching elements of the set of groups, wherein the set of groups is ordered first in the hierarchal arrangement;
adding one or more of the plurality of groups to the set of groups, wherein the or each additional group is ordered next in the hierarchal arrangement; and
then carrying out the compensation procedure for the switching elements of the set of groups including the or each additional group.

12. The method according to claim 11, further including randomising the order of the groups in the hierarchal arrangement and/or randomising the type of hierarchal arrangement used, prior to carrying out the compensation procedure for the switching elements of the plurality of groups.

13. The method according to claim 11, wherein the hierarchal arrangement includes a tree or star topology.

14. A switching valve comprising a plurality of series-connected switching elements and a plurality of auxiliary circuits, each auxiliary circuit being connected in parallel with a respective one of the plurality of series-connected switching elements, each auxiliary circuit including a respective auxiliary capacitor,
wherein the switching valve further includes a controller programmed to carry out a compensation procedure, the controller is programmed to initiate a turn-off event by sending a respective turn-off control signal to each switching element, the controller includes a measuring device configured to measure a respective capacitor voltage value of each auxiliary capacitor after the turn-off event, the controller is programmed to compare the measured capacitor voltage values, and the controller is programmed to use the comparison between the measured capacitor voltages as a reference to adjust the time of sending a or a respective turn-off control signal to at least one of the switching elements so as to reduce a or a respective time difference between the turn-off times of the switching elements at the next turn-off event.

15. The switching valve according to claim 14, wherein the controller includes a plurality of local control units and a higher-level control unit, each local control unit is programmed to send a respective turn-off control signal to the corresponding switching element, each local control unit is configured to be in communication with the higher-level control unit, each local control unit is programmed to transmit the measured capacitor voltage value of the corresponding auxiliary capacitor to the higher-level control unit, the higher-level control unit is programmed to compare the measured capacitor voltage values and to use the comparison between the measured capacitor voltages as a reference to adjust the time of sending a or a respective turn-off control signal to at least one of the switching elements so as to reduce a or a respective time difference between the turn-off times of the switching elements at the next turn-off event, and the higher-level control unit is programmed to transmit the or each adjusted time to the or each corresponding local control unit.

16. The switching valve according to claim 15, wherein each local control unit is configured to be in communication with the higher-level control unit via a passive optical network.

17. The switching valve according to claim 14, wherein each auxiliary circuit includes a snubber circuit.

18. The switching valve according to claim 17, wherein each snubber circuit is a capacitor-diode snubber circuit or a resistor-capacitor-diode snubber circuit.

19. The switching valve according to claim 14, wherein each switching element is a self-commutated switching element.

20. The switching valve according to claim 14, wherein reducing the or each time difference between the turn-off times of the switching elements at the next turn-off event includes: minimising the or each time difference; or reducing the or each time difference to zero.

21. The switching valve according to claim 14, wherein the controller is programmed to compare the measured capacitor voltage values so as to determine at least one time difference between the turn-off times of the switching elements, and the comparison between the measured capacitor voltages includes the or each determined time difference between the turn-off times of the switching elements.

22. The switching valve according to claim 21, wherein the controller is programmed to compare the measured capacitor voltage values so as to determine at least one time difference between the turn-off times of the switching elements based on a correlation between measured capacitor voltage value and time difference between the turn-off times of the switching elements.

23. The switching valve according to claim 22, wherein the controller is programmed to establish a correlation between measured capacitor voltage value and time difference between the turn-off times of the plurality of series-connected switching elements.

24. The switching valve according to claim 22, wherein the controller is programmed to use the comparison between the measured capacitor voltage values as a reference to adjust the correlation between measured capacitor voltage value and time difference between the turn-off times of the switching elements.

25. The switching valve according to claim 14, wherein the controller is programmed to:
group the plurality of series-connected switching elements into a plurality of groups, each group including two or more of the plurality of series-connected switching elements;
for each group, carry out the compensation procedure for the switching elements of the same group; and
then carry out the compensation procedure for the switching elements of the plurality of groups.

26. The switching valve according to claim 25, wherein the controller is programmed to carry out the compensation procedure for the switching elements of the plurality of groups by:
carrying out the compensation procedure for the switching elements of a set of groups, wherein the set of groups includes two or more of the plurality of groups;
adding one or more of the plurality of groups to the set of groups; and
then carrying out the compensation procedure for the switching elements of the set of groups including the or each additional group.

27. The switching valve according to claim 26, wherein the controller is programmed to order the groups in a hierarchal arrangement, and the controller is further programmed to carry out the compensation procedure for the switching elements of the plurality of groups by:
carrying out the compensation procedure for the switching elements of the set of groups, wherein the set of groups is ordered first in the hierarchal arrangement;
adding one or more of the plurality of groups to the set of groups, wherein the or each additional group is ordered next in the hierarchal arrangement; and
then carrying out the compensation procedure for the switching elements of the set of groups including the or each additional group.

28. A switching valve according to claim 27, wherein the controller is programmed to randomise the order of the groups in the hierarchal arrangement and/or randomise the type of hierarchal arrangement used, prior to carrying out the compensation procedure for the switching elements of the plurality of groups.

29. A switching valve according to claim 27, wherein the hierarchal arrangement includes a tree or star topology.
